(19) United States
(12) Patent Application Publication
(10) Pub. No.: US 2016/0071763 A1
(43) Pub. Date: Mar. 10, 2016

(54) METHOD OF MANUFACTURING SEMICONDUCTOR DEVICE

(71) Applicant: Kabushiki Kaisha Toshiba, Minato-ku (JP)

(72) Inventor: Koutarou SHO, Yokkaichi Mie (JP)

(73) Assignee: Kabushiki Kaisha Toshiba, Minato-ku (JP)

(21) Appl. No.: 14/591,338

(22) Filed: Jan. 7, 2015

Related U.S. Application Data
(60) Provisional application No. 62/047,726, filed on Sep. 9, 2014.

(51) Int. Cl. H01L 21/768; H01L 27/115

(52) U.S. Cl. CPC H01L 21/76816; H01L 27/11582; H01L 21/76825; H01L 21/76877

(57) ABSTRACT

According to one embodiment, at first, while a resist pattern is used as a mask, a first set of one of the first layers and one of the second layers, which is an uppermost set in a stacked body and is exposed, is etched. Then, a hardening layer having a predetermined thickness is formed on an upper side of the resist pattern. Thereafter, slimming is performed to the resist pattern in its in-plane direction perpendicular to its thickness direction. The slimming is completed after the hardening layer is entirely removed or at the same time when the hardening layer is entirely removed. Then, while the resist pattern is used as a mask, a set of one of the first layers and one of the second layers is etched at an exposed area of the stacked body.

### CROSS-REFERENCE TO RELATED APPLICATIONS

This application is based upon and claims the benefit of priority from U.S. Provisional Application No. 62/047,726, filed on Sep. 9, 2014; the entire contents of which are incorporated herein by reference.

### FIELD

Embodiments described herein relate generally to a method of manufacturing a semiconductor device.

### BACKGROUND

In recent years, since scaling of semiconductor devices has been advanced, there has been proposed a three-dimensional device including memory cells of a stacked structure. In general, the three-dimensional device is designed such that strings are formed in a direction perpendicular to the substrate surface and so wirings are led out to the periphery of the memory cell formation region. In this case, the wirings are formed in a step-wise state. For example, the step-wise wirings are formed, as follows: At first, a large number of insulating films and metal films are stacked, and a stacked body is thereby formed. Then, a thick resist pattern having an opening at a predetermined area is formed on the stacked body. Then, a set of one insulating film and one metal film is etched at an area corresponding to the opening of the resist pattern by use of an RIE (Reactive Ion Etching) method. Thereafter, the resist pattern is downsized by slimming. Then, while this resist pattern is used as a mask, a set of one insulating film and one metal film is etched by use of an RIE method. Then, the processes of from the slimming of the resist pattern to the etching of a set of one insulating film and one metal film are repeated. Consequently, the step-wise wirings are formed.

However, the slimming process employs isotropic etching, and so it increases the resist consumption. Accordingly, the number of steps that can be processed by use of a resist pattern formed by one lithography process is limited by that much. Further, along with an increase in the number of stacked layers of the three-dimensional device, the number of lithography processes becomes larger. Consequently, the manufacturing cost is increased.

### BRIEF DESCRIPTION OF THE DRAWINGS

FIG. 1 is a perspective view showing an example of a configuration of a memory cell array in a semiconductor device according to an embodiment;

FIG. 2 is an enlarged sectional view showing a portion where a channel body penetrates a plurality of conductive layers and interlayer insulating layers;

FIG. 3 is a sectional view showing an example of a structure of a contact region according to the embodiment; and

FIGS. 4A to 4I are sectional views showing an example of a sequence of a method of manufacturing the contact region according to the embodiment.

### DETAILED DESCRIPTION

In general, according to one embodiment, a stacked body by alternately stacking a plurality of first layers and a plurality of second layers is formed above a substrate. Then, a resist pattern is formed above the stacked body. Thereafter, a first set of one of the first layers and one of the second layers, which is an uppermost set in the stacked body and is exposed from the resist pattern used as a mask is etched. Then, a hardening layer having a predetermined thickness is formed on an upper side of the resist pattern. Thereafter, slimming the resist pattern in its in-plane direction perpendicular to its thickness direction is performed until when a contact formation region adjacent to an etched area of an upper surface of the stacked body is exposed. At this time, the slimming is completed after the hardening layer is entirely removed or at the same time when the hardening layer is entirely removed. Then, a set of one of the first layers and one of the second layers is etched at an area of the stacked body exposed from the resist pattern thus slimmed and used as a mask.

An exemplary embodiment of a method of manufacturing a semiconductor device will be explained below in detail with reference to the accompanying drawings. The present invention is not limited to the following embodiment. The sectional views and the perspective view of a semiconductor device used in the following embodiment are schematic, and so the relationship between the thickness and width of each layer and/or the thickness ratios between respective layers may be different from actual states.

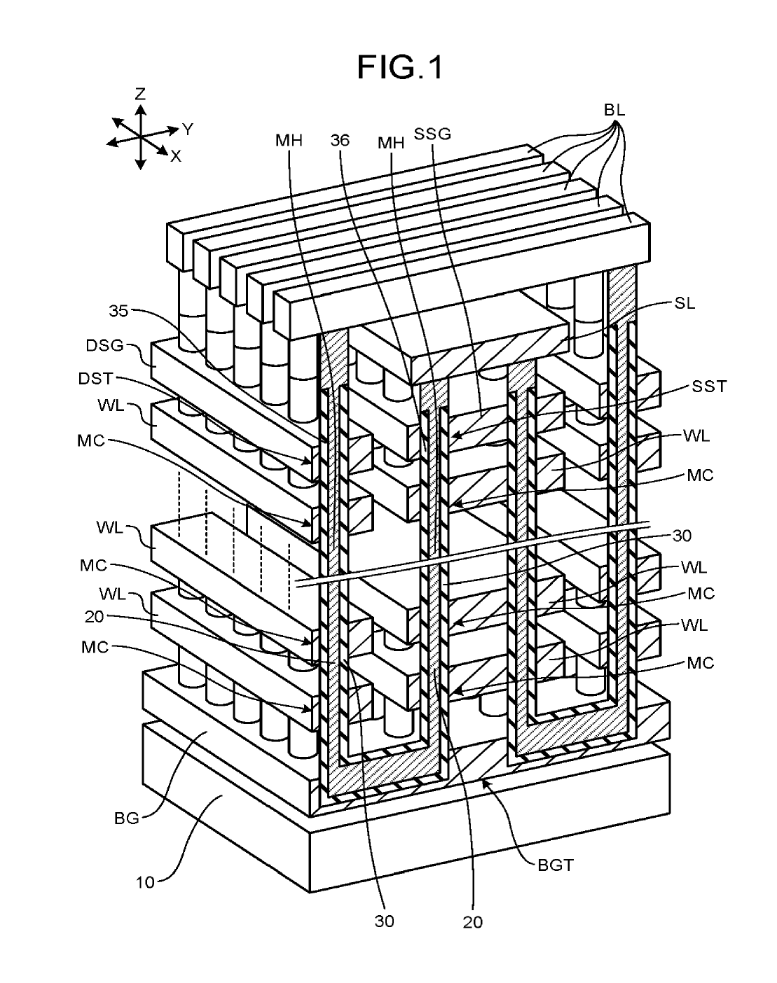

FIG. 1 is a perspective view showing an example of a configuration of a memory cell array in a semiconductor device according to an embodiment. It should be noted that FIG. 1 does not show insulating portions other than insulating films formed in memory holes MH for the sake of easy viewing. Further, in the following embodiment, for example, silicon is employed as a semiconductor, but a semiconductor other than silicon may be employed.

Further, in this specification, an XYZ orthogonal coordinate system is introduced for the sake of explanation. This coordinate system is assumed such that two directions parallel to the main surface of a substrate 10 and orthogonal to each other are an X-direction and a Y-direction, and that a direction orthogonal to both of the X-direction and the Y-direction is a Z-direction.

A back gate BG is arranged through an insulating layer (not shown) above the substrate 10. For example, the back gate BG is made of a silicon layer doped with an impurity and thereby having conductivity. Above the back gate BG, a plurality of conductive layers WL and insulating layers (not shown) are alternately stacked in the Z-direction. For example, each of the conductive layers WL is made of a silicon layer doped with an impurity and thereby having conductivity.

The conductive layers WL are divided into a plurality of blocks by slits extending in the X-direction. Accordingly, the conductive layers WL extend in the X-direction. Drain side selection gates DSG are arranged each through an insulating layer (not shown) on that one of the conductive layers WL which is present on the uppermost side of a certain block. For example, each of the drain side selection gates DSG is made of a silicon layer doped with an impurity and thereby having conductivity. A source side selection gate SSG is arranged through an insulating layer (not shown) on that one of the conductive layers WL which is present on the uppermost side of another block adjacent to the block mentioned above. For example, the source side selection gate SSG is made of a silicon layer doped with an impurity and thereby having conductivity.

A source line SL is arranged through an insulating layer (not shown) above the source side selection gate SSG. For example, the source line SL is made of a silicon layer doped with an impurity and thereby having conductivity. Alternatively, the source line SL may be made of a metal material. A plurality of bit lines BL are arranged through an insulating layer (not shown) above the source line SL and the drain side selection gates DSG. Each of the bit lines BL extends in the Y-direction.

A plurality of memory holes MH each having a U-shape are formed in the stacked body above the substrate 10 described above. The U-shaped memory holes MH are composed of holes categorized into the following three types. In the block including each drain side selection gate DSG, holes are formed such that each of them extends in the Z-direction and penetrates the drain side selection gate DSG and the underlying conductive layers WL. Further, in the block including the source side selection gate SSG, holes are formed such that each of them extends in the Z-direction and penetrates the source side selection gate SSG and the underlying conductive layers WL. These two types of holes are respectively connected by holes formed in the back gate BG and extending in the Y-direction.

In each of the memory holes MH, a channel body 20 made of a U-shaped silicon layer is arranged. A gate insulating film 35 is formed on the sidewall of each of the memory holes MH between the drain side selection gate DSG and the channel body 20. A gate insulating film 36 is formed on the sidewall of each of the memory holes MH between the source side selection gate SSG and the channel body 20.

An insulating film 30 is formed on the sidewall of each of the memory holes MH between the respective conductive layers WL and the channel body 20. The insulating film 30 is also formed on the inner wall of each of the memory holes MH between the back gate BG and the channel body 20. For example, the insulating film 30 has an ONO (Oxide-Nitride-Oxide) structure including a pair of silicon oxide films and a silicon nitride film sandwiched between them.

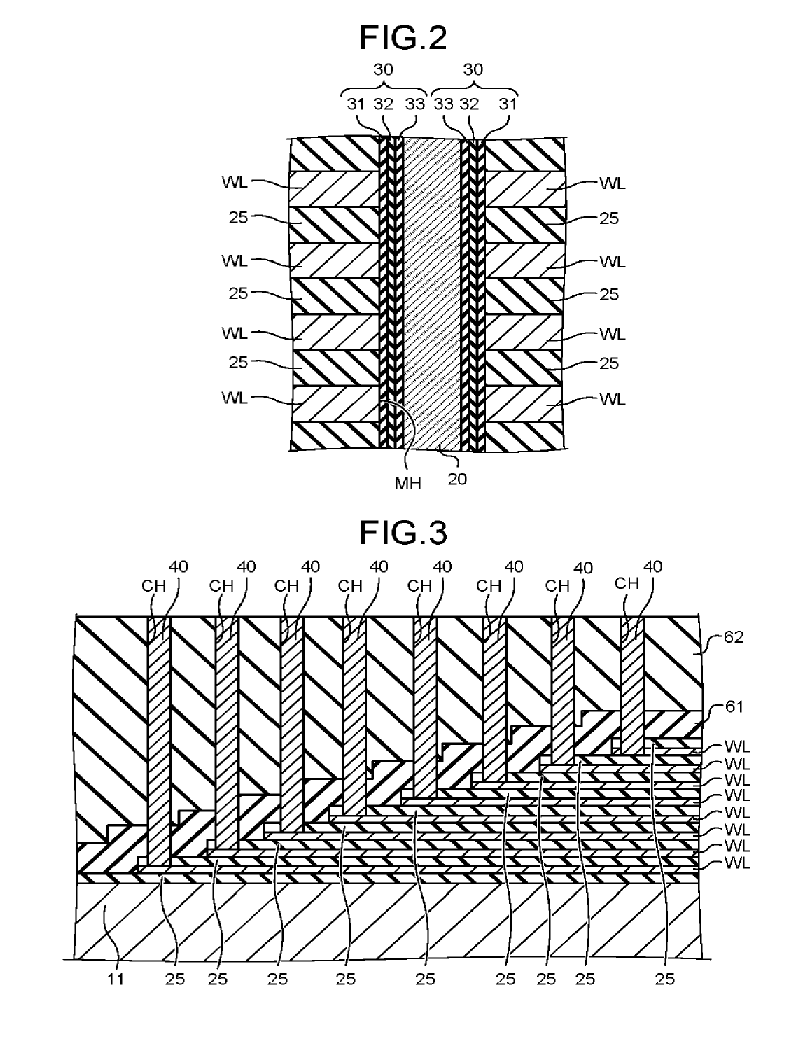

FIG. 2 is an enlarged sectional view showing a portion where a channel body penetrates a plurality of conductive layers and interlayer insulating layers. FIG. 2 shows insulating layers between the conductive layers WL, as insulating layers 25, which are not shown in FIG. 1.

Between each of the conductive layers WL and the channel body 20, a first insulating film 31, a charge accumulation film 32, and a second insulating film 33 are formed in this order from the side of the conductive layers WL. The first insulating film 31 is set in contact with the conductive layers WL, the second insulating film 33 is set in contact with the channel body 20, and the charge accumulation film 32 is interposed between the first insulating film 31 and the second insulating film 33.

The channel body 20 serves as a channel, each of the conductive layers WL serves as a control gate, and the charge accumulation film 32 serves as a data storage layer for accumulating a charge injected from the channel body 20. In other words, memory cells are formed at points of intersection between the channel body 20 and the respective conductive layers WL, such that each of them has a structure in which a control gate surrounds a channel.

The semiconductor device according to this embodiment is a nonvolatile semiconductor memory device that can electrically and freely perform erasing and writing of data and can hold stored contents even after the power is turned off. For example, the memory cells are memory cells each having a charge trap structure. The charge accumulation film 32 includes a large number of traps for confining charges (electrons), and, for example, it is made of a silicon nitride film. For example, the second insulating film 33 is made of a silicon oxide film, and it serves as a potential barrier when a charge is injected from the channel body 20 into the charge accumulation film 32 or when the charge accumulated in the charge accumulation film 32 is diffused into the channel body 20. For example, the first insulating film 31 is made of a silicon oxide film, and it prevents the charge accumulated in the charge accumulation film 32 from being diffused into the conductive layers WL.

With reference to FIG. 1 again, a drain side selection transistor DST is composed of each drain side selection gate DSG, the channel bodies 20 penetrating the drain side selection gate DSG, and the gate insulating films 35 present between these channel bodies 20 and the drain side selection gate DSG. The upper end portion of each of the channel bodies 20 protruding upward from the drain side selection gate DSG is connected to the corresponding one of the bit lines BL.

A source side selection transistor SST is composed of the source side selection gate SSG, the channel bodies 20 penetrating the source side selection gate SSG, and the gate insulating films 36 present between these channel bodies 20 and the source side selection gate SSG. The upper end portion of each of the channel bodies 20 protruding upward from the source side selection gate SSG is connected to the source line SL.

A back gate transistor BGT is composed of the back gate BG, the channel bodies 20 extending through the back gate BG, and the gate insulating films 30 present between the back gate BG and these channel bodies 20.

Between each of the drain side selection transistors DST and the back gate transistor BGT, a plurality of memory cells MC respectively using the conductive layers WL as control gates are arranged, and so the number of memory cells MC corresponds to the number of conductive layers WL.

Similarly, between the back gate transistor BGT and the source side selection transistor SST, a plurality of memory cells MC respectively using the conductive layers WL as control gates are arranged, and so the number of memory cells MC corresponds to the number of conductive layers WL.

These memory cells MC, each of the drain side selection transistors DST, the back gate transistor BGT, and the source side selection transistor SST are connected in series, so that one memory string having a U-shape is fabricated. A plurality of memory strings each formed in this manner are arrayed in the X-direction and the Y-direction, so that a plurality of memory cells MC are structured in the X-direction, the Y-direction, and the Z-direction, i.e., in a three-dimensional state.

FIG. 3 is a sectional view showing an example of a structure of a contact region according to the embodiment. The contact region is a region where contact electrodes are arranged to connect the respective conductive layers WL and upper side wirings. This contact region is present outside the memory cell array region shown in FIG. 1, when viewed in the X-direction.

Part of the stacked body composed of a plurality of conductive layers WL and a plurality of insulating layers 25 forms a stepped structural section that has been processed in a step-wise state within the contact region. This stepped structural section is covered with a stopper layer 61, and an interlayer insulating film 62 is provided on the stopper layer 61. For example, the stopper layer 61 is made of silicon nitride, and the interlayer insulating film 62 is made of silicon oxide.

A plurality of contact holes CH are formed in the interlayer insulating film 62 and the stopper layer 61, and contact electrodes 40 are respectively provided in the contact holes CH.

Each of the contact holes CH penetrates the interlayer insulating film 62, the stopper layer 61, and the corresponding one of the insulating layers 25, and reaches the one of the conductive layers WL at the corresponding step. For example, the contact holes CH are filled with tungsten serving as the contact electrodes 40. The conductive layers WL are respectively connected to upper side wirings (not shown) through the contact electrodes 40.

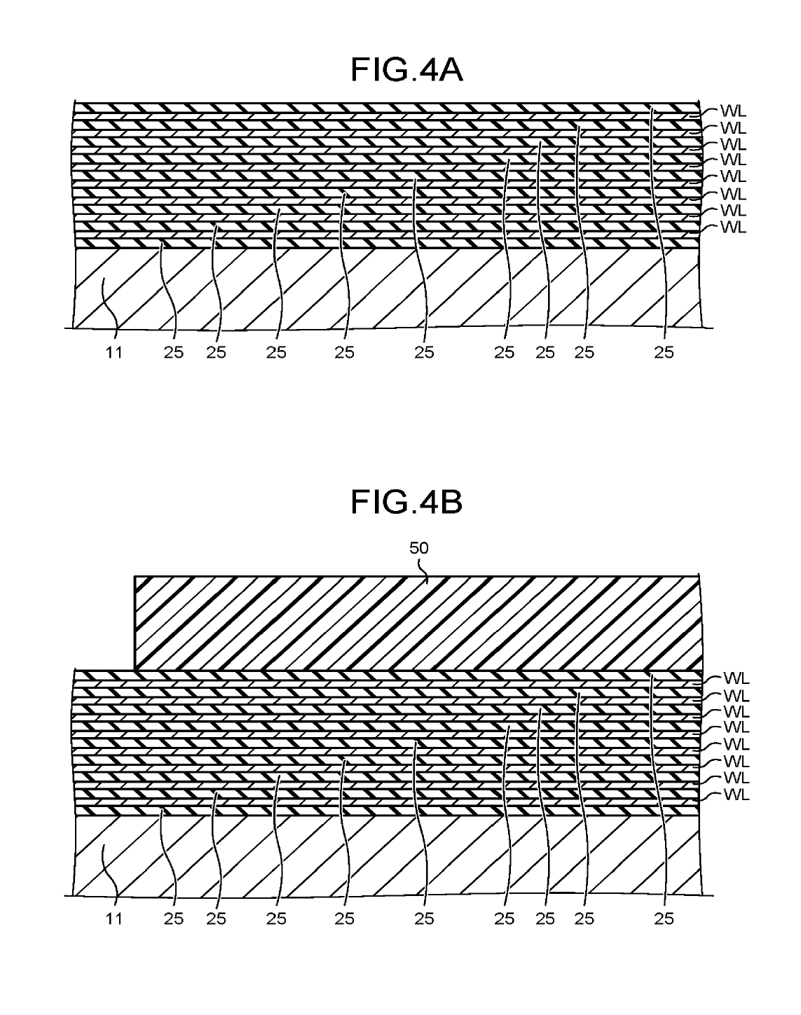

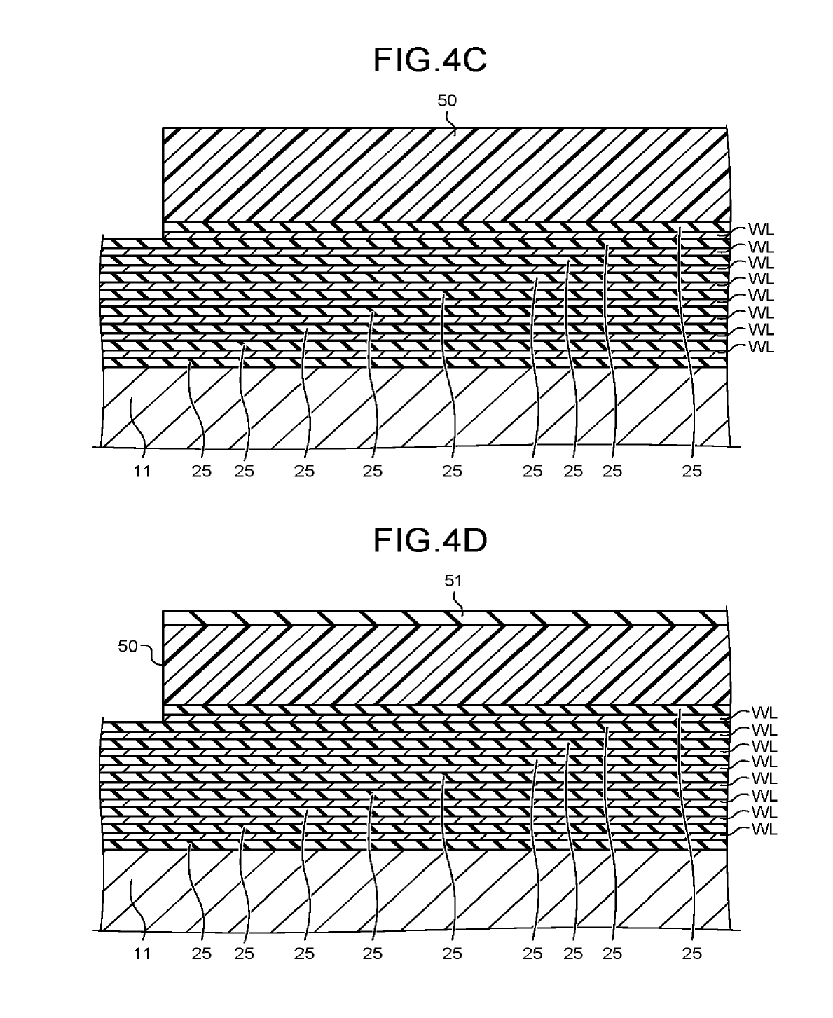

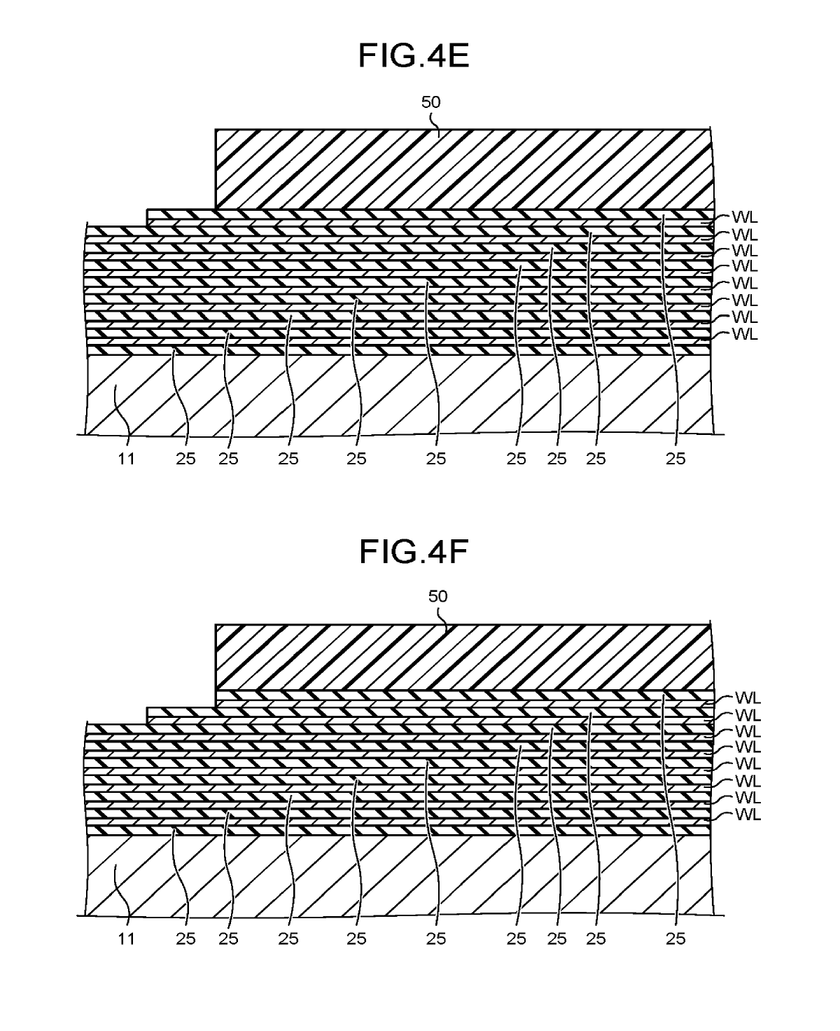

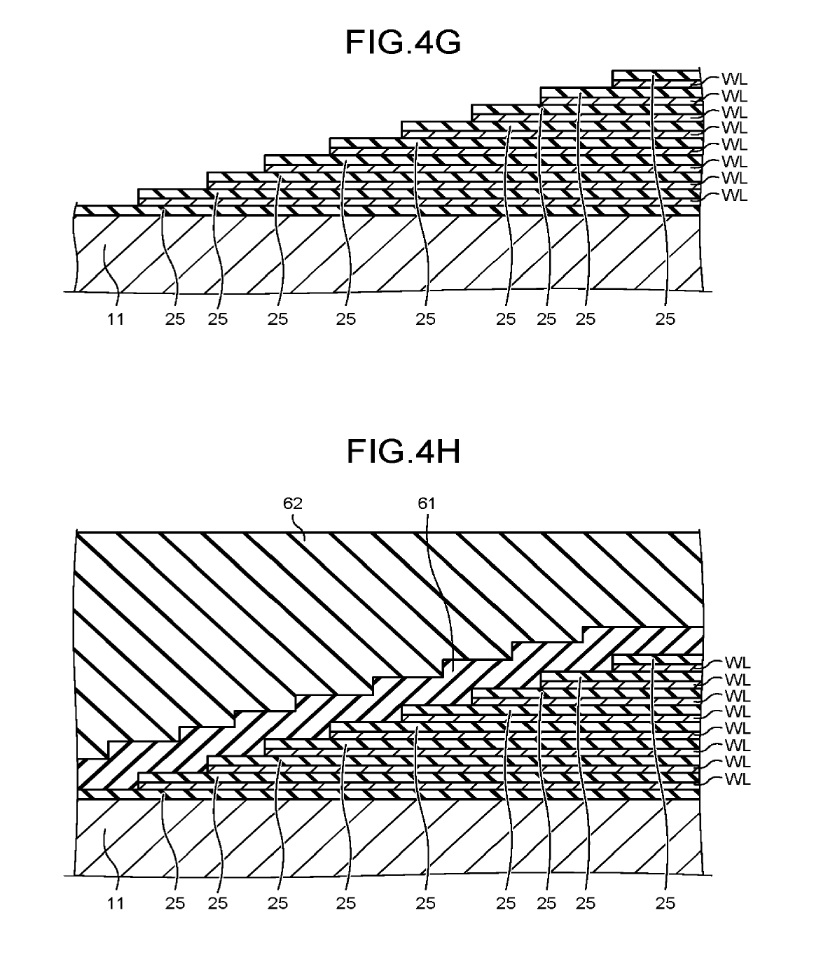

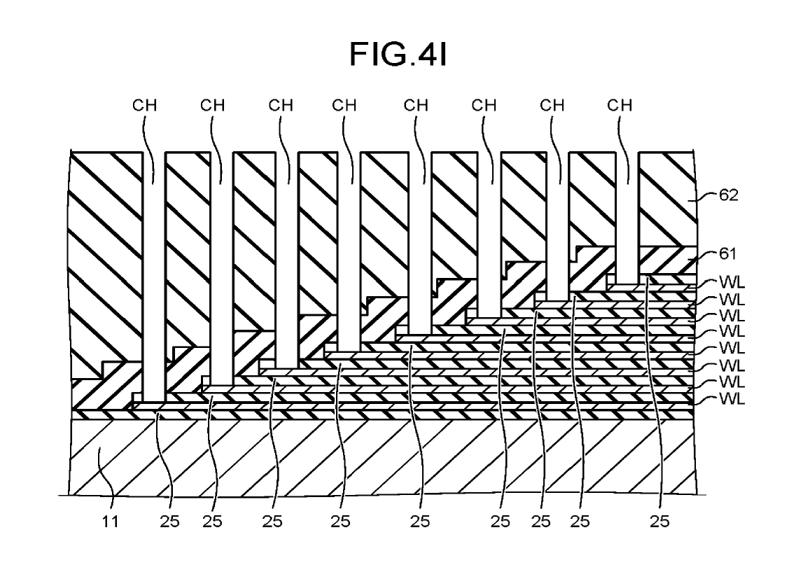

Next, an explanation will be given of a method of forming this step-wise contact region. FIGS. 4A to 4I are sectional views showing an example of a sequence of a method of manufacturing the contact region according to the embodiment. At first, as shown in FIG. 4A, a plurality of insulating layers 25 and a plurality of conductive layers WL are alternately stacked above a base body 11, so that a stacked body composed of these layers is formed. The conductive layers WL shown in FIG. 4A are exemplified by eight layers, but the number of conductive layers WL may be arbitrarily set.

It should be noted that the base body 11 includes the substrate 10, the back gate BG, and the interlayer insulating layer between them, as shown in FIG. 1. The back gate BG in the memory cell array region is provided with recessed portions corresponding to the bottoms of the U-shaped memory strings, before the stacked body of the insulating layers 25 and the conductive layers WL is fabricated. Then, these recessed portions are filled with a sacrificial film, and, thereafter, the insulating layers 25 and the conductive layers WL are stacked.

Each of the insulating layers 25 is made of a silicon oxide layer mainly containing silicon oxide. Each of the conductive layers WL is made of a silicon layer doped with an impurity and thereby having conductivity, or a tungsten (W) film. For example, the insulating layers 25 and the conductive layers WL are formed by a CVD (Chemical Vapor Deposition) method. Further, each of the insulating layers 25 and the conductive layers WL may have a film thickness of, e.g., 50 nm.

After this stacked body is fabricated, the memory cell array region is subjected to processes of forming the memory cells MC, the drain side selection transistors DST, the source side selection transistor SST, the back gate transistor BGT, and so forth. Holes are formed to penetrate the stacked body in the vertical direction (stacking direction), and then the sacrificial film embedded in the recessed portions of the back gate BG are removed through the holes. Consequently, the U-shaped memory holes MH are formed. Then, on the inner wall of each of the memory holes MH, the insulating film 30 including the charge accumulation film 32 is formed, and a silicon layer serving as the channel body is further formed on its inner side. After the memory cell array is fabricated as described above, the contact region is subjected to a sequence of processes as described below.

At first, as shown in FIG. 4B, a resist is applied to the stacked body. For example, as shown in FIG. 4B, this resist coating is provided to the uppermost one of the insulating layers 25. Then, a resist pattern 50 is formed by patterning the resist into a desired shape by use of a lithography technique and a development technique. At this time, the patterning is performed such that the resist pattern 50 comes to have an opening at an area in the contact region corresponding to the area for forming the one of the contact electrodes 40 to be connected to the lowermost one of the conductive layers WL.

Thereafter, as shown in FIG. 4C, while the resist pattern 50 is used as a mask, the one of the insulating layers 25 exposed from the resist pattern 50 and the one of the conductive layers WL below it are partly removed by use of an RIE method. In other words, a set of one insulating layer 25 and one conductive layer WL, exposed on the uppermost side of the stacked body, is etched.

Then, as shown in FIG. 4D, a hardening process is performed to the surface (upper surface) of the resist pattern 50. For example, the hardening process to the resist pattern 50 may be performed by an irradiation process with UV (UltraViolet) light or EB (Electron Beam). In the irradiation process with UV light or EB, the surface of the resist pattern 50 is irradiated with UV light or EB, so that the resist is cross-linked. This cross-linked portion of the resist serves as a hardening layer 51, which improves the etching resistance of the resist pattern 50.

Further, for example, the hardening process to the resist pattern 50 may be performed by a silylation process. According to the silylation process, the resist pattern 50 is brought into contact with a silicon-containing compound, such as hexamethyldisilazane, in a vapor phase, so that the surface of the resist pattern 50 reacts with the compound to form a silylation layer. This silylation layer serves as a hardening layer 51, which improves the etching resistance of the resist pattern 50.

Alternatively, for example, the hardening process to the resist pattern 50 may be performed by an ion implantation process. According to the ion implantation process, As, B, or the like is implanted into the upper surface of the resist pattern 50 by use of an ion implantation technique to form a hardening layer 51 on the surface of the resist pattern 50. This hardening layer 51 improves the etching resistance of the resist pattern 50.

Further, the hardening process to the resist pattern 50 may be performed by a deposition process associated with an RIE method. According to the deposition process associated with an RIE method, for example, a fluorocarbon-based gas having a high adsorption coefficient is used, so that the etching process is performed while the resist pattern mask is protected by deposition of a relatively thick fluorocarbon polymer. The fluorocarbon polymer film serves as a hardening layer 51, which improves the etching resistance of the resist pattern 50.

Then, as shown in FIG. 4E, in a state where the hardening layer 51 is present on the upper surface of the resist pattern 50, the slimming is performed to reduce the planar size of the resist pattern 50. This slimming is performed by an isotropic plasma etching process. For example, oxygen (O₂) gas and chlorine (Cl₂) gas are supplied into a process chamber, and plasma is generated inside the process chamber. In this state, the base body 11 is put in the plasma while no power is applied to the stage that holds the base body 11, so that the resist pattern 50 is isotropically etched.

In this slimming process, the resist pattern 50 is reduced by a predetermined size, such as the width of a contact formation region, in a direction parallel to the substrate surface. The contact formation region is a region where one contact electrode 40 connected to one conductive layer WL is arranged, and corresponds to one step in the stepped structural section. Since the hardening layer 51 is present on the upper surface of the resist pattern 50, the resist pattern 50 is etched from the side surface. Further, the etching rate is larger at the side surface as compared with the upper surface on which the hardening layer 51 is present. Then, the slimming is completed after the hardening layer 51 is entirely removed or at the same time when the hardening layer 51 is entirely removed. Accordingly, the hardening layer 51 is formed to have a thickness to satisfy such a condition. Since the side surface of the resist pattern 50 is set back from the state shown in FIG. 4D, part of the surface of the uppermost one of the insulating layers 25 is newly exposed. Thus, the resist pattern 50 is prepared to form the next step of the step-wise pattern.

Thereafter, as shown in FIG. 4F, while the resist pattern 50 is used as a mask, the one of the insulating layers 25 exposed from the resist pattern 50 and the one of the conductive layers WL below it are partly removed by use of an RIE method. Consequently, a set of one insulating layer 25 and one conductive layer WL (the conductive layer WL of the second set from the top), which is below the set removed by the preceding etching, is partly removed. Further, the set of one insulating layer 25 and one conductive layer WL (the conductive layer WL of the first set from the top), which is exposed from the resist pattern 50 adjacently to the second set, is also partly removed.

Thereafter, the processes respectively shown in FIGS. 4D to 4F described above are repeatedly performed. Specifically, the processes repeated a plurality of times include forming a hardening layer 51 on the upper surface of the resist pattern 50, further slimming the resist pattern 50 with the hardening layer 51 present thereon, and etching a set of one insulating layer 25 and one conductive layer WL at an area exposed from the slimmed resist pattern 50 serving as a mask. Consequently, the stepped structural section shown in FIG. 4G is obtained.

In the explanation described above, the memory cell array region and the contact region are fabricated by stacking the insulating layers 25 and the conductive layers WL. However, the conductive layers WL may be formed of sacrificial layers made of a material different from that of the insulating layers 25. In this case, hollow portions are formed by selectively removing the sacrificial layers by etching. Then, the hollow portions are filled with a conductive film, such as a metal film of, e.g., tungsten (W) or a silicon layer doped with an impurity and thereby having conductivity.

Thereafter, as shown in FIG. 4H, the stopper layer 61 is formed to cover the stepped structural section. For example, the stopper layer 61 is made of silicon nitride. Further, the interlayer insulating film 62 is formed on the stopper layer 61. The interlayer insulating film 62 is made of a material, such as silicon oxide, different from that of the stopper layer 61. Then, the upper surface of the interlayer insulating film 62 is planarized by use of, e.g., a CMP (Chemical Mechanical Polishing) method.

Then, a mask film (not shown) is formed on the interlayer insulating film 62. The mask film includes openings at positions corresponding to the respective steps of the stepped structural section. These openings define a pattern for forming contact holes. Thereafter, as shown in FIG. 4I, while the mask film is used as a mask, the interlayer insulating film 62, the stopper layer 61, and the insulating layers 25 immediately below the stopper layer 61 are selectively etched by use of an RIE method. Consequently, a plurality of contact holes CH are formed in the interlayer insulating film 62, the stopper layer 61, and the insulating layers 25 immediately below the stopper layer 61. The plurality of contact holes CH respectively have depths different from each other from the upper surface of the interlayer insulating film 62. Each of the contact holes CH penetrates the interlayer insulating film 62, the stopper layer 61, and the corresponding one of the insulating layers 25 immediately below the stopper layer 61, and reaches the one of the conductive layers WL at the corresponding step.

The plurality of contact holes CH are formed together at the same time. Since the plurality of conductive layers WL have been processed in a step-wise state, the plurality of contact holes CH respectively reaching the conductive layers WL can be formed together by the same etching process; which is efficient. At this time, the stopper layer 61 made of silicon nitride serves as an etching stopper in etching the interlayer insulating film 62 made of silicon oxide.

Thereafter, as shown in FIG. 3, the contact electrodes 40 are embedded in the contact holes CH. Specifically, at first, a first barrier film (such as a titanium film) is formed on the inner wall of the contact holes CH. Then, a second barrier film (such as a titanium nitride film) is formed on the inner side of the first barrier film. Further, a material superior in filling property, such as tungsten, is embedded on the inner side of the second barrier film. The first and second barrier films prevent the tungsten (W) from being diffused. Further, the first and second barrier films also serve as adhesion layers respectively adhering to the inner wall of the contact holes CH and the tungsten. With the processes described above, the semiconductor device including the contact region is fabricated.

It should be noted that the shape of the memory strings is not limited to the U-shape, but may be an I-shape that linearly extends in the stacking direction of the plurality of conductive layers WL. Further, the structure of the insulating film between the conductive layers WL and each channel body 20 is not limited to the ONO (Oxide-Nitride-Oxide) structure, but may be a 2-layer structure formed of a charge accumulation layer and a gate insulating film, for example.

According to an ordinary method of manufacturing a semiconductor device, when slimming of the resist pattern 50 is performed, isotropic etching is used, because the etching is made to proceed in the planar direction (lateral direction) to reduce the planar size of the resist pattern. Thus, there may be a case where it is etched in the film thickness direction (vertical direction) by an amount almost the same as that in the lateral direction. Particularly, when the stacked body is more multilayered and the number of steps in the stepped structural section is thereby larger, the number of times to perform the resist slimming needs to be increased. Consequently, it may happen that the resist pattern 50 is consumed entirely in the film thickness direction, in the middle of the sequence. In this case, in the middle of processing the stepped structural section, it becomes necessary to transfer the wafer to a light exposure unit and a development unit, so as to perform resist coating again and perform patterning of a resist pattern 50 by lithography and development.

According to this embodiment, before the resist slimming is performed, the hardening layer 51 is formed on the upper surface of the resist pattern 50. The hardening layer 51 can reduce the consumption of the resist pattern 50 in the thickness direction when the resist slimming is performed. Consequently, one resist pattern 50, which is formed by resist coating, lithography, and development, can be used to process a larger number of steps as compared with the conventional technique. In ether words, it is possible to reduce the number of processes of performing resist coating, light exposure, and development, in fabricating the stepped structural section.

Further, the film thickness of the hardening layer 51 is set at a thickness necessary for slimming the resist pattern 50 by a predetermined amount, it is almost vanished when the slimming process is finished. Consequently, it is possible to limit the amount of losing the resist pattern 50 to the necessary minimum, during the slimming process. Moreover, it is possible to exclude the necessity of additionally performing a process of removing the hardening layer 51 even if the hardening layer 51 is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming a stacked body by alternately stacking a plurality of first layers and a plurality of second layers above a substrate;
forming a resist pattern above the stacked body;
etching a first set of one of the first layers and one of the second layers, which is an uppermost set in the stacked body and is exposed from the resist pattern used as a mask;
forming a hardening layer having a predetermined thickness on an upper side of the resist pattern;
slimming the resist pattern in its in-plane direction perpendicular to its thickness direction until when exposing a contact formation region adjacent to an etched area of an upper surface of the stacked body, such that the slimming is completed after the hardening layer is entirely removed or at the same time when the hardening layer is entirely removed; and
etching a set of one of the first layers and one of the second layers, at an area of the stacked body exposed from the resist pattern thus slimmed and used as a mask.

2. The method of manufacturing a semiconductor device according to claim 1, the method comprises repeatedly performing processes of from the forming of the hardening layer to the etching of the set of one of the first layers and one of the second layers to make the stacked body in a step-wise state, after the etching of the set of one of the first layers and one of the second layers.

3. The method of manufacturing a semiconductor device according to claim 1, wherein in the forming of the hardening layer, the hardening layer is formed by irradiating the resist pattern with UV light or EB.

4. The method of manufacturing a semiconductor device according to claim 1, wherein in the forming of the hardening layer, the hardening layer is formed by performing a silylation process to the resist pattern.

5. The method of manufacturing a semiconductor device according to claim 1, wherein in the forming of the hardening layer, the hardening layer is formed by performing an ion implantation process to the resist pattern.

6. The method of manufacturing a semiconductor device according to claim 5, wherein ion implantation of D or As is performed to the resist pattern.

7. The method of manufacturing a semiconductor device according to claim 1, wherein in the forming of the hardening layer, the hardening layer is formed by performing an RIE process under conditions that generate a fluorocarbon polymer film on an upper surface of the resist pattern.

8. The method of manufacturing a semiconductor device according to claim 1, wherein
each of the first layers is a conductive film, and
each of the second layers is an insulating film.

9. The method of manufacturing a semiconductor device according to claim 1, wherein
each of the first layers is a first insulating film, and
each of the second layers is a second insulating film made of a material different from that of the first insulating films.

10. The method of manufacturing a semiconductor device according to claim 9, further comprising,
removing, after making the stacked body in a step-wise state, the second layers by etching to form hollow portions, and
embedding a conductive film in the hollow portions.
